(19) United States
(12) Patent Application Publication
(10) Pub. No.: US 2007/0045840 A1
(43) Pub. Date: Mar. 1, 2007

(54) METHOD OF SOLDER BUMPING A CIRCUIT COMPONENT AND CIRCUIT COMPONENT FORMED THEREBY

(75) Inventor: Michael J. Varnau, Russiaville, IN (US)

Correspondence Address: HARTMAN & HARTMAN, P.C., 552 EAST 700 NORTH, VALPARAISO, IN, 46383, US

(73) Assignee: DELPHI TECHNOLOGIES, INC., Kokomo, IN (US)

(21) Appl. No.: 11/162,224

(22) Filed: Sep. 1, 2005

(51) Int. Cl. H01L 23/48; H01L 21/44

(52) U.S. Cl. 257/737; 438/613; 257/772; 257/E23.02; 257/E23.021

(57) ABSTRACT

A circuit component and method by which degradation of a solder connection by electromigration can be prevented or reduced. The component generally includes an interconnect pad on a surface of the component, a metallic multilayer structure overlying the interconnect pad and having a solderable surface layer, and a solder material on the multilayer structure. According to a preferred aspect of the component and method, a stud is wire-bonded to the solderable surface layer of the multilayer structure and encased by the solder material to provide a low electrical resistance path through the solder material.

### BACKGROUND OF THE INVENTION

The present invention generally relates to integrated circuit (IC) devices attached by solder bumps. More particularly, this invention relates to a method of solder bumping a circuit component to yield a solder connection that is resistant to electromigration.

A flip chip is attached to circuit board or other suitable substrate with beadlike terminals formed on interconnect pads located on one surface of the chip. The terminals are typically in the form of solder bumps near the edges of the chip, which are reflowed to both secure the chip to the circuit board and electrically interconnect the flip chip circuitry to a conductor pattern on the circuit board. Reflow soldering techniques generally require that a controlled quantity of solder or solder paste is deposited on the chip pads using methods such as electrodeposition and printing. The solder or solder paste is then heated above the melting or liquidus temperature of the solder alloy (for eutectic and noneutectic alloys, respectively) to form the solder bumps on the pads. After cooling to solidify the solder bumps, the chip is soldered to the conductor pattern by registering the solder bumps with their respective conductors and then reheating, or reflowing, the solder so as to form solder connections that metallurgically adhere to the conductors.

Aluminum or copper metallization is typically used in the fabrication of integrated circuits, including the interconnect pads on which the solder bumps of a flip chip are formed. Thin layers of aluminum or copper are chemically deposited on the chip surface, and then selectively etched to achieve the desired electrical interconnects on the chip. The number of metal layers used for this purpose depends on the complexity of the integrated circuit, with a minimum of two metal layers typically being needed for even the most basic devices. Aluminum and its alloys are generally unsolderable and susceptible to corrosion if left exposed, and copper is readily dissolved by molten solder. Consequently, a diffusion barrier layer is required on top of copper interconnect metal, while an adhesion layer is required for aluminum interconnect metal. These layers, along with one or more additional metal layers, are deposited to form what is termed an under bump metallurgy (UBM) whose outermost layer is readily solderable, i.e., can be wetted by and will metallurgically bond with solder alloys of the type used for solder bumps.

FIG. 1 represents a cross-sectional view through the surface of a die 10 on which a UBM 20 has been formed to receive a solder bump (not shown). The UBM 20 is formed on an interconnect pad 12, defined by a portion of an aluminum runner exposed through an opening in a passivation layer 22 that covers the surface of the die 10. While a three-layer UBM 20 is illustrated in FIG. 1, a variety of UBM structures have been proposed. In the example of FIG. 1, the three-layer UBM 20 may comprise an adhesion-promoting layer 14, a solderable layer 16, and a solderable, oxidation-resistant layer 18. The adhesion layer 14 may be aluminum or another metal composition that will bond to the underlying aluminum interconnect pad 12. Copper is readily solderable, i.e., can be wetted by and will metallurgically bond with solder alloys of the type used for solder bumps, and therefore is a common choice for the oxidation-resistant layer 18 of the UBM 20. The solderable layer 16 may be a nickel-vanadium or chromium-copper alloy, to which the solder metallurgically bonds after the oxidation-resistant layer 18 dissolves into the solder during the bumping and reflow operations. In FIG. 1, a mask 24 is shown as having been formed on the die 10, with an opening 26 patterned in the mask 24 to enable a controlled quantity of solder paste (not shown) to be deposited onto the UBM 20.

Following solder deposition, bumping, and die attachment, the resulting solder bump forms a solder connection that carries electrical current in and out of the die 10, such that an inherent potential difference is established between the two ends of the bump, i.e., the end attached to the die 10 and the opposite end attached to the substrate. It has been observed that, in combination with operating temperature, high electrical current densities through a solder bump connection can lead to a phenomenon known as “electromigration,” especially in low melting point solder alloys (e.g., eutectic SnPb) commonly used in electronic assemblies. In its simplest form, electromigration, as it relates to the die 10 represented in FIG. 1, can be defined as the separation and movement of the metallic phases within the solder bump, such as tin and lead phases within a bump formed of a Sn—Pb solder alloy. In other words, the solder bump, which is essentially a homogenous mixture of these phases, becomes segregated with one or more phases accumulating near the die 10 and one or more other phases accumulating near the substrate. This segregation is detrimental to the long term reliability and performance of the solder bump connection, and in some cases can lead to “electrically open” solder joints. Another detrimental phenomenon that occurs with solder bump connections is associated with dissolution of the solderable layer 16 of the UBM 20, and interacts with the electromigration phenomenon by increasing the local current density as a result of reducing the area capable of efficiently carrying the electrical current.

Electromigration is typically the limiting factor for determining the maximum current capability for a flip chip IC. Therefore, if electromigration can be reduced, the IC can be rated for higher current with the same IC design. Alternatively, increasing the allowed current density permits an IC to be designed smaller and less costly. For these reasons, flip chip solder connections used in high power applications, such as output drivers for automotive engine controllers, are of particular interest when addressing electromigration, and efforts have been made to improve their reliability by increasing their current-carrying capability. One such approach is to electroplate a copper pillar as part of the UBM structure, as described in U.S. Pat. No. 6,429,531. The pillar provides a low electrical resistance path into the center of the solder bump, and provides much more surface area that decreases the current density through the connection. The copper pillar also serves as a source of copper to form a desirable SnCu intermetallic with tin in a SnPb solder. This intermetallic forms a thick SnCu intermetallic layer on portions of the UBM not covered by the copper pillar, which reduces or eliminates dissolution of the UBM solderable layer. However, the relatively thick plated copper pillar causes high mechanical stress on the surface of the silicon IC and it's interconnect and passivation structures, which can lead to fracture of those structures due to mechanical and/or environmental stresses.

### BRIEF SUMMARY OF THE INVENTION

The present invention provides a circuit component and method by which degradation of a solder connection by electromigration can be prevented or at least reduced.

The circuit component generally includes an interconnect pad on a surface of the circuit component, a metallic multilayer structure overlying the interconnect pad, and a solder material on the multilayer structure. The component further includes a stud that has been wire-bonded to a solderable surface layer of the multilayer structure and encased by the solder material to provide a low electrical resistance path through the solder material.

The method of this invention generally entails providing the interconnect pad on the circuit component surface, forming the metallic multilayer structure overlying the interconnect pad, wire-bonding the stud to the solderable surface layer of the multilayer structure, and then depositing the solder material on the multilayer structure to encase the stud without substantially dissolving the stud so that the stud provides a low electrical resistance path through the solder material. As used herein, “without substantially dissolving the stud” means that any dissolution of the stud is limited to the external surface of the stud, such that the bulk of the stud remains intact.

In view of the above, it can be seen that the stud within the solder material defines part of the conductive path through the solder material. By forming the stud of a highly conductive material, such as copper, the stud can provide a low electrical resistance path through the solder material to advantageously decrease the current density through an electrical connection subsequently formed by the solder material. If the stud is formed of copper and the solder material contains tin, such as a SnPb solder, the stud can also serve as a source of copper to form a desirable SnCu intermetallic layer capable of reducing or eliminating dissolution of the multilayer structure.

According to a preferred aspect of the invention, the wire-bonding placement of the stud enables the stud to be selectively placed only where needed, for example, within those solder bumps that must carry a relatively large current. In a typical power control IC devices, for example, this aspect of the invention typically can result in studs being placed in fewer than half of the solder bumps of a device, as opposed to current practice where the majority of bumps typically carry a high current.

Other advantages of the present invention include the relatively low cost of incorporating a wire bonding step into a solder bumping operation that can otherwise be entirely conventional aside from the wire-bonding operation, and the minimally negative and potentially beneficial affect that studs formed of appropriate material have on the thermal resistance of the solder connections containing the studs. As a result, incorporation of studs does not negatively affect the thermal management of the device, and if formed of a highly thermally conductive material such as copper, can increase the thermal conductivity of a solder connection. Accordingly, the stud can promote heat flow through the connection and reduce the temperature of the connection, further reducing the tendency for electromigration to occur.

Other objects and advantages of this invention will be better appreciated from the following detailed description.

### BRIEF DESCRIPTION OF THE DRAWINGS

FIG. 1 is a cross-sectional side view of a surface region of a circuit component and shows a solder bump interconnect pad with an UBM in accordance with the conventional practice.

FIGS. 2 through 5 depict additional process steps carried out on the circuit component of FIG. 1 to produce a solder bump with an encased stud in accordance with the present invention.

### DETAILED DESCRIPTION OF THE INVENTION

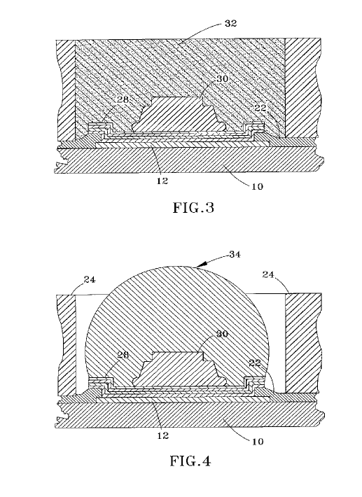

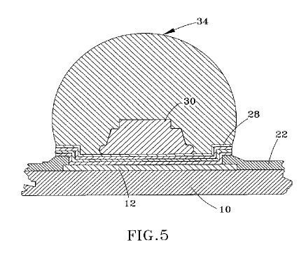

FIGS. 1 through 5 represent partial cross-sectional views of a surface region of a semiconductor die 10, such as a flip chip, as it is prepared for and then undergoes solder bumping in accordance with the present invention. As described previously, FIG. 1 shows the surface of the die 10 as being protected by a passivation layer 22 that, as known in the art, protects the die 10 from environmental contaminants, moisture, and electrical shorts. The passivation layer 22 is typically silicon dioxide, though silicon nitride, polyimides, phosphosilicated glass (PSG), borophosphosilicated glass (BPSG), or organic layers such as polyimide, BCB (benzocyclobutene), or PBO (polybutylene oxide) may also be used. A portion of a runner is exposed by an opening in the passivation layer 22, defining what is termed herein an interconnect pad 12. The runner and pad 12 can be conventionally formed of aluminum or an aluminum-base alloy, which renders the pad 12 generally unsolderable and susceptible to corrosion if left exposed. For this reason, the pad 12 is covered with a UBM 20 that provides a solderable surface for a solder bump 34 (FIGS. 4 and 5) formed by reflowing a solder material 32 (FIG. 3) deposited on the UBM 20. While only a single pad 12 is shown in the Figures, it is to be understood that the die 10 will have a number of pads 12 defined in a similar manner.

The UBM 20 is shown in the Figures as being formed of three metallic layers 14, 16, and 18, though UBM's formed of different numbers of layers are also within the scope of this invention. The layer 14 shown contacting the interconnect pad 12 is referred to herein as an adhesion layer 14, for the reason that the adhesion layer 14 directly contacts and metallurgically bonds to the interconnect pad 12. The second layer 16 overlying the adhesion layer 14 is referred to herein as a solderable layer 16, over which the outermost layer 18 of the UBM 20 is deposited. The terms used to describe the layers of the UBM 20 are based on known thin-film UBM constructions, such as a sputtered Al—NiV—Cu metallization in which the adhesion layer 14 is aluminum, the solderable layer 16 is NiV, and the outermost layer 18 is copper. Other suitable materials for the adhesion layer 14 include titanium, chromium, tungsten, and potentially other materials capable of adhering to the aluminum pad 12 and the surrounding passivation layer 22, as represented in FIG. 1. NiV alloys are desirable for the solderable layer 16 in that, in addition to being solderable relative to SnPb solder alloys, it reduces solid state diffusion through the UBM 20. Other materials suitable for the solderable layer 16 include chromium-copper and palladium. In addition to copper, gold and other oxidation-resistant metals that are both solderable and capable of protecting the solderable layer 16 are suitable for the outermost layer 18. A suitable thickness for the UBM 20 is about one to about two micrometers, though greater and lesser thicknesses are possible. It should be noted that the UBM 20 could be omitted if the interconnect pad 12 were sufficiently thick and formed of a solderable material, e.g., copper, silver, gold, etc.

In a preferred embodiment, the UBM 20 is used in combination with a solder material (32 in FIG. 3) based on tin-based solder alloy systems, though the use of other solder alloys is within the scope of this invention. As evident from FIG. 3, the solder material 32 is deposited on the UBM 20 through an opening 26 in a mask 24. The solder material 32, preferably in the form of a solder paste containing a mixture of solder alloy particles, a flux compound, a carrier, rheological modifiers, etc., is deposited on the mask 24 and forced into the opening 26, such as with a squeegee. The mask 24 is preferably formed of a thick photoimageable solder resist material that meets the feature definition and thickness requirements for the process used to deposit the solder material 32 onto the UBM 20 and yield a solder bump 34 (FIG. 4) having adequate height and volume to produce the desired solder connection.

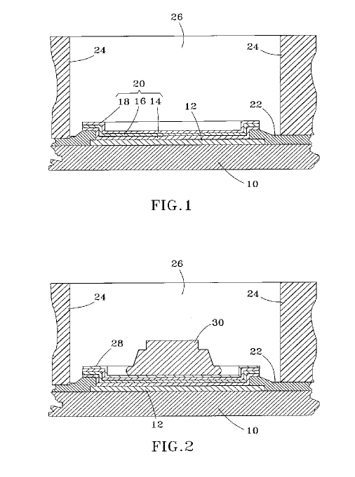

FIG. 2 shows an optional oxidation-resistant, solderable and solder-soluble layer 28 deposited over the UBM 20. The solder-soluble layer 28 is preferably a noble metal, such as gold, silver, or palladium, and is used to protect the outermost layer 18 of the UBM 20 from oxidation during the bumping process, but is preferably dissolved by the completion of reflow. As such, the UBM 20 is provided with a solderable outer surface defined by the outermost layer 18 or the optional solder-soluble layer 28. A suitable thickness for the solder-soluble layer 28 is about 0.5 micrometers. The solder-soluble layer 28 can be deposited using a known immersion or electroless plating process.

After depositing the UBM 20 and, if used, the optional solder-soluble layer 28, a stud 30 is formed on the UBM 20 as shown in FIG. 2. According to a preferred aspect of the invention, the stud 30 is placed on and bonded to the UBM 20 as a solid body using a wire bonder apparatus of a type known and used in copper wire-bonding processes. As such, the apparatus (not shown) is adapted to make a small, well-controlled bond achieved with such techniques as thermosonic and ultrasonic bonding performed at an elevated temperature (e.g., about 150° C.) and within an inert or reducing gas atmosphere to minimize oxidation of the stud 30. Commercial examples of wire bonders that can be adapted for use with this invention include the WaferPRO Plus stud bumper available from Kulicke and Soffa Industries, Inc., and an ESEC gold wire bonder modified with an ESEC COWI-2 copper conversion kit available from Unaxis USA Inc. The use of wire bonders is also desirable from the standpoint of being able to selectively place studs 30 on only those UBM's 20 of the die whose solder bump connections are prone to electromigration, such as those solder bump connections that have relatively high current flows. Because the placement and bonding process performed by wire bonders is the preferred technique for bonding the stud 30 to the UBM 20, the process of attaching the stud 30 to the UBM 20 is referred to herein as “wire-bonding” because it is descriptive of the placement and bonding process and the equipment suitable therefore, though it is to be understood that a wire is not used or bonded as an interconnection during the process of this invention.

As represented in FIG. 2, the geometry and size of the stud 30 is compatible with the opening 26 in the mask 24 through which the bonder must place and bond the stud 30. The stud 30 is preferably preshaped by the bonding process to have the geometry shown in FIG. 2. To have a significant affect on the electrical conductivity and current density of the solder bump 34, the stud 30 is preferably placed at the center of the UBM 20 (and therefore the center of the solder bump 34), occupies at least 40% of the surface area of the UBM 20, and occupies at least 20% of the total height of the solder bump 34 (FIG. 4). A preferred material for the stud 30 is copper, as copper has a greater electrical conductivity than SnPb solders and other widely-used solder alloys, resulting in lower current densities near the edges of the solder bump 34 to reduce electromigration rates. Copper also has a greater thermal conductivity than SnPb solders and many other solder alloys, thereby further reducing electromigration rates as a result of lower bump temperatures. Finally, a copper stud 30 has the advantage of providing excess copper during bumping and reflow, which reduces the dissolution rates of certain components of the UBM 20, such as nickel within the solderable layer 16. However, other materials could be used for the stud 30, notable examples of which include gold, silver, palladium, and platinum. However, in all cases the solder material 32 and the eventual solder bump 34 encase the stud 30 without dissolving any significant portion of the stud 30. In other words, the solder material 32 dissolves at most surface regions of the stud 30, with the bulk of the stud 30 remaining unaffected by subsequent post-placement processing.

FIG. 3 represents the die surface as it appears following deposition of the solder material 32, in which the opening 26 in the mask 24 is entirely filled with the solder material 32 to completely encase the stud 30 and provide sufficient solder alloy for the desired solder bump 34. As such, it is believed that the bulk of the opening 26 in the mask 24 should be filled with the solder material 32. The top of the stud 30 preferably remains below the top of the surface of the mask 24 to facilitate the deposition of the solder material 32 into the opening 26 by such techniques as a squeegee or another printing process. FIG. 4 represents the result of heating the solder material 32 to its bumping reflow temperature, causing the flux within the material 32 to vaporize or burned off and the solder alloy particles to melt and coalesce to form the semi-spherical bump 34 on the UBM 20. Finally, FIG. 5 shows the result of removing the mask 24 to ready the die 10 for mounting to a circuit board or other appropriate substrate (not shown), by which the solidified solder bump 34 is registered with one of any number of conductors on the circuit board and then reheated to a suitable chip mount reflow temperature to remelt and bond the die 10 to the conductor. As previously noted, because not all solder bump connections of the die 10 may be prone to electromigration, such as any solder bump connections that have relatively low current flows, other solder bump connections on the die 10 can be formed identically to the solder bump 34 except for the omission of the stud 30.

While the invention has been described in terms of a preferred embodiment, it is apparent that other forms could be adopted by one skilled in the art. A notable example is to form the noncollapsing layer 34 of silver, and the second solder layer 38 of tin. In this embodiment, the UBM 20 would not need to be formed of a solderable material, and the noncollapsing layer 34 and the second solder layer 38 would form a low MP solder (within the end region 42) to join the noncollapsing layer 34 to the conductor 16 during reflow. Other metal combinations are foreseeable with the invention. Accordingly, the scope of the invention is to be limited only by the following claims.

1. A circuit component comprising:
an interconnect pad on a surface of the circuit component;
a metallic multilayer structure overlying the interconnect pad and having a solderable surface layer;
a preformed solid stud wire-bonded to the solderable surface layer of the multilayer structure, the stud being formed of copper or a copper alloy; and
a solder material on the multilayer structure and encasing the stud so that the stud provides a low electrical resistance path through the solder material.

2. The circuit component according to claim 1, wherein the multilayer structure comprises a first metallic layer on the interconnect pad and a second metallic layer defining the solderable surface layer of the multilayer structure to which the stud is wire-bonded.

3. The circuit component according to claim 2, wherein the second metallic layer is an oxidation-resistant metal.

4. The circuit component according to claim 2, wherein the second metallic layer is a noble metal.

5. The circuit component according to claim 2, further comprising a copper layer between the first and second metallic layers.

6. The circuit component according to claim 1, wherein the solder material is a tin-lead alloy.

7.-20. (canceled)
